(19) United States
(12) Patent Application Publication
(10) Pub. No.: US 2026/0129876 A1
(43) Pub. Date: May 7, 2026

(54) SEMICONDUCTOR DEVICE

(71) Applicant: Samsung Electronics Co., Ltd., Suwon-si (KR)

(72) Inventors: Jaeho JEONG, Suwon-si (KR); Bonghyun CHOI, Suwon-si (KR)

(21) Appl. No.: 19/332,249

(22) Filed: Sep. 18, 2025

(30) Foreign Application Priority Data
Nov. 1, 2024 (KR) 10-2024-0153182

(51) Int. Cl. H01L 23/00; H01L 25/065; H01L 25/18; H10B 80/00

(52) U.S. Cl. CPC H10B 80/00; H10W 90/00; H10W 72/01931; H10W 72/01953; H10W 72/9445; H10W 90/792

(57) ABSTRACT

A semiconductor device includes a first semiconductor substrate including a first semiconductor device, a second semiconductor substrate including a second semiconductor device, and a bonding region that is between the first semiconductor device and the second semiconductor device and includes a first region, a second region, and a third region that is between the first region and the second region and extends around the first region, where the bonding region includes: a first bonding pad on the first region, a second bonding pad on the second region, and a third bonding pad on the third region, and where the third bonding pad extends around the first bonding pad.

### CROSS-REFERENCE TO RELATED APPLICATION

The present application claims priority to Korean Patent Application No. 10-2024-0153182, filed on Nov. 1, 2024, the entire contents of which are incorporated herein for all purposes by this reference.

### TECHNICAL FIELD

The present disclosure relates to a semiconductor device.

### BACKGROUND

A semiconductor device may be a component used to control or amplify electrical signals in electronic devices, and various types of semiconductor devices may be manufactured. For example, a memory device may be used to store and retrieve data, and a non-memory device may be used to control or amplify electrical signals. A semiconductor device is a desirable element in electronic devices, and is desirable in various industries such as computers, communication equipment, consumer electronics, etc.

A process of bonding two (2) or more wafers by using a hybrid bonding technique, etc. may be used to improve the integration of semiconductor devices. In the wafer bonding process, defects occur due to, for example, particles remaining between wafers. Therefore, measures for ensuring the reliability of semiconductor devices may be desired.

### SUMMARY

The present disclosure aims to provide a semiconductor device with improved electrical characteristics and reliability.

According to some embodiments of the present disclosure, a third bonding pad may be placed to surround or extends around a bonding pad disposed in a region that performs a target or predetermined electrical operation to prevent or inhibit the propagation of voids or cracks to the region during a subsequent heat treatment process, a dividing process, a reliability evaluation process, etc. Accordingly, the reliability of semiconductor devices may be improved by preventing or inhibiting the quality deterioration or the defect occurrence of the semiconductor devices.

According to some embodiments of the present disclosure, the third bonding pad may be formed to have a closed shape (e.g., a closed curve shape) to prevent or inhibit the occurrence of unbonded portions or voids during the bonding process of the third bonding pad. Accordingly, the reliability of semiconductor devices may be improved.

According to some embodiments of the present disclosure, a semiconductor device may include a first semiconductor substrate including a first semiconductor device, a second semiconductor substrate including a second semiconductor device, and a bonding region that is between the first semiconductor device and the second semiconductor device and includes a first region, a second region, and a third region that is between the first region and the second region and extends around the first region, where the bonding region includes: a first bonding pad on the first region, a second bonding pad on the second region, and a third bonding pad on the third region, and where the third bonding pad extends around the first bonding pad.

According to some embodiments of the present disclosure, a semiconductor device may include a substrate, a peripheral circuit structure on the substrate, a cell structure on the peripheral circuit structure, and a bonding region including a first bonding pad, a second bonding pad, and a third bonding pad between the peripheral circuit structure and the cell structure, where the first bonding pad is on a first region of the bonding region, where the second bonding pad is on a second region of the bonding region, where the third bonding pad is on a third region of the bonding region, where the third region is between the first region and the second region and extends around the first region, and where the third bonding pad extends around the first bonding pad.

According to some embodiments of the present disclosure, a semiconductor device may include a first semiconductor substrate including a first semiconductor device, a second semiconductor substrate including a second semiconductor device, and a bonding region that is between the first semiconductor device and the second semiconductor device and includes a first region, a second region, and a third region between the first region and the second region and extending around the first region, and where the bonding region includes: a first bonding pad on the first region, where the first bonding pad includes a first bottom bonding pad on the first semiconductor device and a first top bonding pad on the second semiconductor device, a second bonding pad on the second region, where the second bonding pad includes a second bottom bonding pad on the first semiconductor device and a second top bonding pad on the second semiconductor device, and a third bonding pad on the third region, where the third bonding pad includes a third bottom bonding pad on the first semiconductor device and a third upper bonding pad on the second semiconductor device, where the third region entirely extends around the first region in a first direction and a second direction that are parallel to an upper surface of the first semiconductor device, and where the third bonding pad extends in a line shape along the third region and entirely extends around the first region in the first direction and the second direction.

### BRIEF DESCRIPTION OF DRAWINGS

FIG. 1 is a plan view illustrated to explain a semiconductor device according to some embodiments of the present disclosure;

FIG. 2 is a plan view illustrated to explain parts of a chip region according to some embodiments of the present disclosure;

FIG. 3 is an example cross-sectional view taken along line A-A′ of FIG. 1;

FIG. 4 is an example cross-sectional view taken along line A-A′ of FIG. 1;

FIG. 5 is an example cross-sectional view taken along line C-C′ of FIG. 1;

FIG. 6A is an example cross-sectional view taken along line B-B′ of FIG. 1;

FIG. 6B is an example cross-sectional view taken along line B-B′ of FIG. 1;

FIG. 7 is an example cross-sectional view taken along line B-B′ of FIG. 1;

FIG. 8 to FIG. 11 are views illustrated to explain a method for manufacturing a third bonding pad according to some embodiments of the present disclosure;

FIG. 12 is a view illustrating a part of a semiconductor device in which a third bonding pad is formed according to some embodiments of the present disclosure;

FIG. 13 is a view illustrated to explain a semiconductor device according to some embodiments of the present disclosure; and

FIG. 14 is an example block diagram illustrating an electronic system according to some embodiments of the present disclosure.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

With reference to the drawings below, a semiconductor device according to some embodiments of the present disclosure will be described in detail.

A semiconductor device may include a semiconductor wafer including an integrated circuit that performs a predetermined function, a semiconductor chip, etc. Two (2) or more semiconductor chips may be connected by using a bonding pad. The bonding pad may include an operation bonding pad electrically connected to an integrated circuit to perform a bonding function and a dummy bonding pad that is not electrically connected to another element but performs a bonding function only.

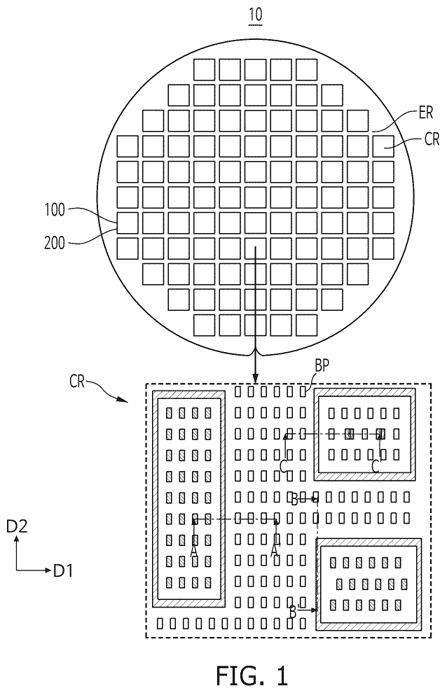

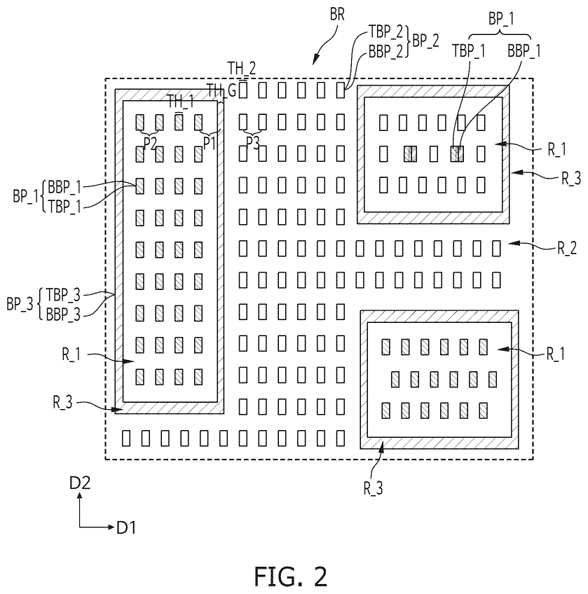

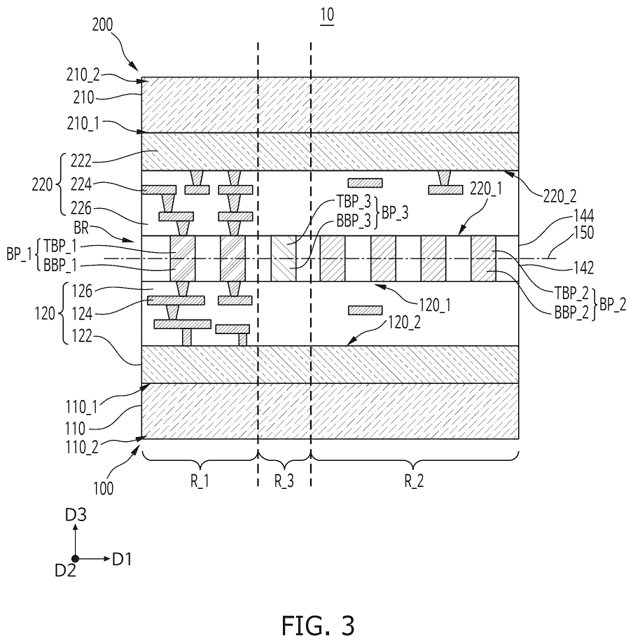

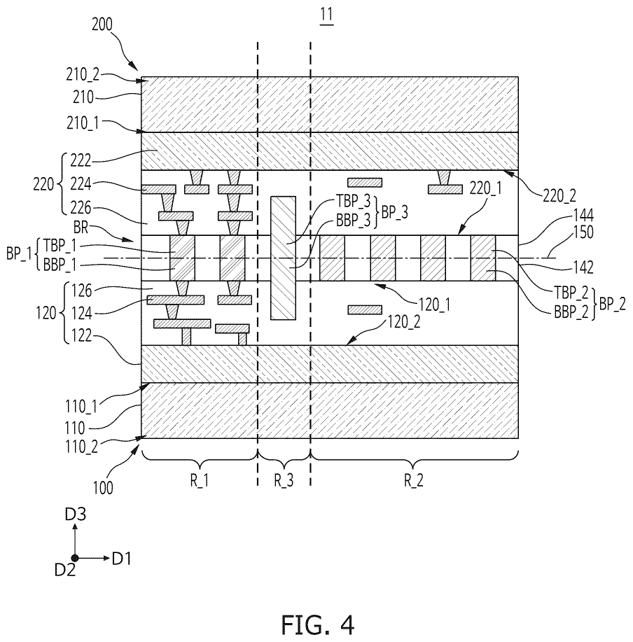

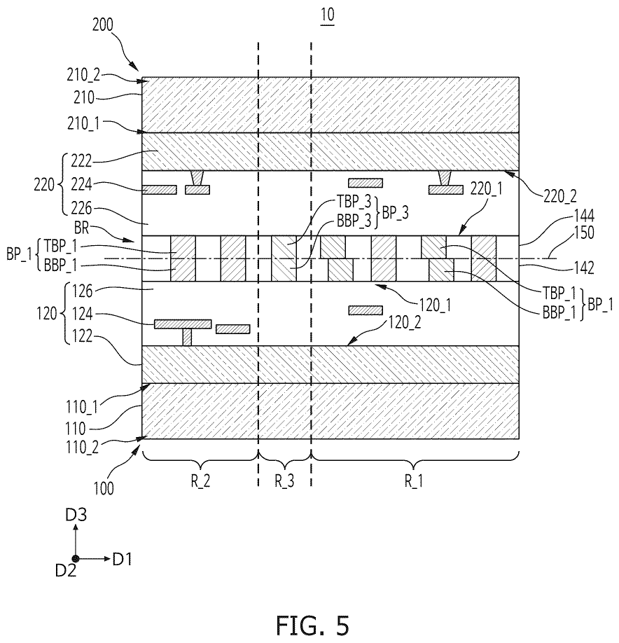

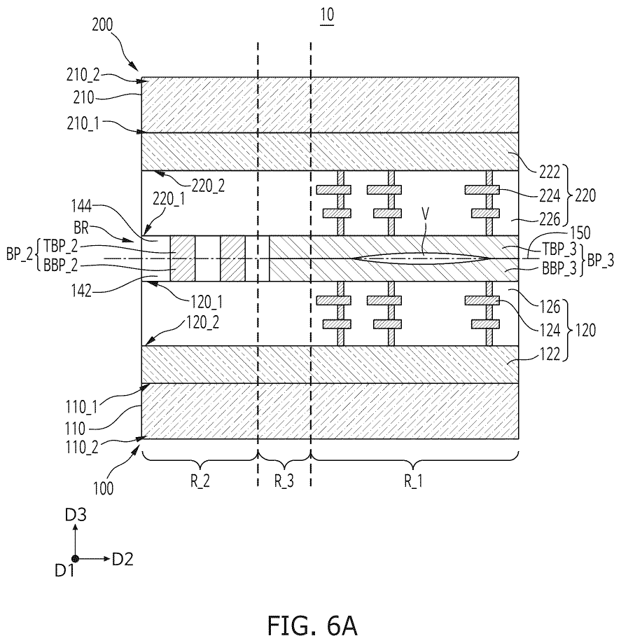

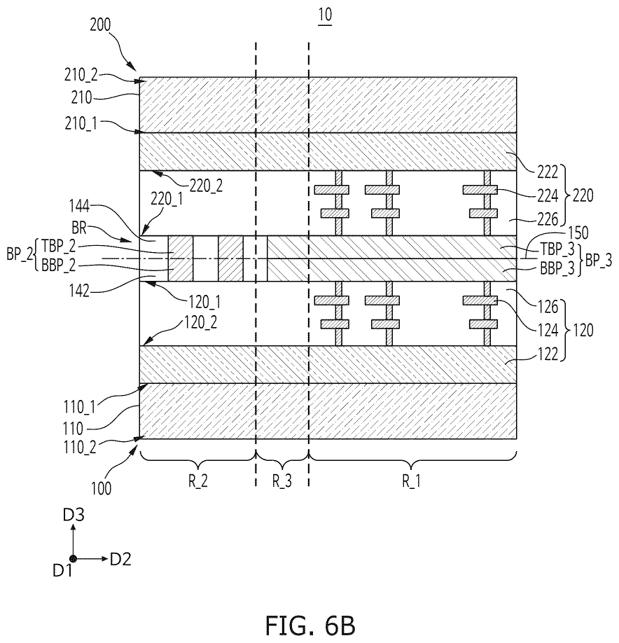

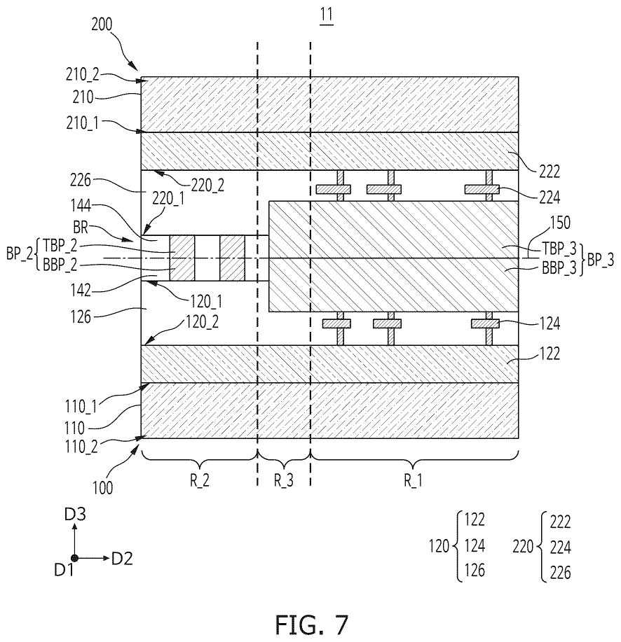

FIG. 1 is a plane view illustrated to explain a semiconductor device 10 according to some embodiments of the present disclosure. FIG. 2 is a plan view illustrated to explain parts of a chip region CR. according to some embodiments of the present disclosure. FIG. 3 is an example cross-sectional view taken along line A-A′ of FIG. 1. FIG. 4 is an example cross-sectional view taken along line A-A′ of FIG. 1. FIG. 5 is an example cross-sectional view taken along line C-C′ of FIG. 1. FIG. 6A is an example cross-sectional view taken along line B-B′ of FIG. 1. FIG. 6B is an example cross-sectional view taken along line B-B′ of FIG. 1. FIG. 7 is an example cross-sectional view taken along line B-B′ of FIG. 1.

Referring to FIG. 1 and FIG. 2, a semiconductor device 10 according to some embodiments of the present disclosure may be formed by bonding a first semiconductor chip 100 to a second semiconductor chip 200, and may include a chip region CR and an edge region ER.

The chip region CR may be a high-density region with a relatively high pattern density, and the edge region ER may be a low-density region with a relatively low pattern density or without patterns. The chip region CR may include a cell array region of a semiconductor memory device, a peripheral circuit region including circuits to be electrically connected to cell arrays included in the cell array, and a core region. According to some embodiments of the present disclosure, the chip region CR may include a memory device. The chip region CR may include a non-semiconductor device, and the present disclosure is not limited thereto.

The edge region ER may be a region configured to include a portion scribed or cut off when a plurality of chip regions CR are divided into individual chip regions CR. The edge region ER may be referred to as a scribe lane, a scribe line, an external region, an outer region, a cut-off region. The edge region ER may be located at the edge of the chip region CR to form a boundary of the chip region CR.

According to some embodiments of the present disclosure, the chip region CR may include at least one non-volatile memory device. For example, the at least one non-volatile memory device may include NAND flash memory, Vertical NAND flash memory (referred to as ‘VNAND’), NOR flash memory, Resistive Random Access Memory (RRAM), Phase-Change Memory (PRAM), Magnetoresistive Random Access Memory (MRAM), Ferroelectric Random Access Memory (FRAM), Spin Transfer Torque Random Access Memory (STT-RAM), or a combination thereof.

The memory device may be implemented as a three-dimensional array structure. For example, the chip region CR may include a cell array region and a peripheral circuit structure included in the semiconductor device. According to some embodiments of the present disclosure, the memory device may further include a volatile memory device such as a dynamic random access memory (DRAM).

Referring to FIG. 1 to FIG. 3, a chip region CR of a first semiconductor chip 100 and a chip region CR of a second semiconductor chip 200 may face each other for bonding. A bonding region BR may be formed between respective chip regions CR of the first semiconductor chip 100 and the second semiconductor chip 200. At least one bonding pad BP may be disposed on the bonding region BR. A bonding pad BP may be formed by bonding the bonding pad of the first semiconductor chip 100 to the bonding pad of the second semiconductor chip 200. According to some embodiments of the present disclosure, the bonding pad of the first semiconductor chip 100 may be referred to as a lower bonding pad, the bonding pad of the second semiconductor chip 200 may be referred to as a top bonding pad, but may be referred differently according to the locations thereof.

The bonding region BR may include a first region R_1, a second region R_2, and a third region R_3 disposed between the first region R_1 and the second region R_2 and surrounding or extending around the first region R_1.

At least one first bonding pad BP_1 may be arranged in the first region R_1. The first bonding pad BP_1 may be formed by bonding a first bottom bonding pad BBP_1 formed on the first semiconductor chip 100 and a first top bonding pad TBP_1 formed on the second semiconductor chip 200.

The first bonding pad BP_1 may be an operation bonding pad electrically connected to an integrated circuit element included in the chip region CR and performing a bonding function, and the first region R_1 may be an operation region including at least one bonding pad disposed therein. For example, the first bonding pad BP_1 may be electrically connected to integrated circuit elements such as a page buffer, a decoder, or a peripheral circuit to perform a bonding function. Referring to FIG. 2, as illustrated on the right upper side of the bonding region BR, the first bonding pad BP_1 may include a misaligned bonding pad including a non-overlapping area, which is not aligned in the vertical direction (e.g., direction D3 shown in FIG. 3). The misaligned bonding pad may be electrically insulated from another element on the chip region CR to perform a bonding function only, and the first region R_1 may be a susceptible region including at least one misaligned bonding pad disposed therein. Dummy bonding pads may be placed at the periphery of the first bonding pad BP_1 that performs the function of the misaligned bonding pad. The first bonding pad BP_1 that performs the function of the misaligned bonding pad may be spaced apart from the first bonding pad BP_1 that performs the function of the operation bonding pad on the chip region CR. In this case, another first region R_1 constituting a susceptible region may be formed on the chip region CR separately from the first region R_1 constituting an operation region.

At least one second bonding pad BP_2 may be placed on the second region R_2. A second bonding pad BP_2 may be formed by bonding a second bottom bonding pad BBP_2 formed on the first semiconductor chip 100 and a second top bonding pad TBP_2 formed on the second semiconductor chip 200.

The second bonding pad BP_2 may be a dummy bonding pad electrically insulated from another element on the chip region CR to perform a bonding function only, and the second region R_2 may be a dummy region including a dummy bonding pad disposed therein. The second region R_2 may occupy or overlap a substantial portion of the chip region CR, and defects such as impurity particles, voids, etc. may be formed on the second region R_2.

In the third region R_3, a third bonding pad BP_3 may be arranged along the third region R_3. According to some embodiments of the present disclosure, the bonding pad of the first semiconductor chip 100 may be referred to as a third bottom bonding pad BBP_3, and the bonding pad of the second semiconductor chip 200 may be referred to as a third top bonding pad TBP_3, but may be referred to differently according to the locations thereof. The third bonding pad BP_3 may be formed by bonding the third bottom bonding pad BBP_3 formed on the first semiconductor chip 100 and the third top bonding pad TBP_3 formed on the second semiconductor chip 200.

The third bonding pad BP_3 may surround or extend around at least one first bonding pad BP_1. The third bonding pad BP_3 may surround the first region R_1 by extending in a line (or linear) shape along the third region R_3 to form a closed shape (e.g., a closed curve) in the horizontal direction. For example, as illustrated in FIG. 2, the third bonding pad BP_3 may entirely surround or extend entirely around the first region R_1 by extending in a line (or linear) shape along a first direction D1 and a second direction D2 in the third region R_3 to form a closed curve. The third bonding pad BP_3 may surround/extend around and protect/insulate the first bonding pad BP_1, which is referred to as a guard structure.

A line width TH_G of the third bonding pad BP_3 may be less than or equal to a width TH_1 of the first bonding pad BP_1 in the first direction D1 and/or the second direction D2. The line width TH_G of the third bonding pad BP_3 may be less than or equal to a width TH_2 of the second bonding pad BP_2 in the first direction D1 and/or the second direction D2.

A pitch P1 (or distance) between one of the plurality of first bonding pads BP_1 adjacent to the third bonding pad BP_3 may be greater than or equal to a pitch P2 (or distance) between a pair of the plurality of first bonding pads BP_1 or a pitch P3 (or distance) between a pair of plurality of second bonding pads BP_2. A pitch between one of the plurality of second bonding pads BP_2 adjacent to the third bonding pad BP_3 and the third bonding pad BP_3 may be greater than or equal to the pitch P2 between the plurality of first bonding pads BP_1 or the pitch P3 between the plurality of second bonding pads BP_2.

Referring to FIG. 3, a semiconductor device 10 may be formed by bonding a first semiconductor chip 100 having a chip region CR and a second semiconductor chip 200 having a chip region CR by hybrid bonding. The semiconductor device 10 may include a bonding region BR formed between respective chip regions CR of the first semiconductor chip 100 and the second semiconductor chip 200. The bonding region BR may include a first region R_1, a second region R_2, and a third region R_3 disposed between the first region R_1 and the second region R_2. The third region R_3 may surround or extend around the first region R_1 in a closed curve shape in the horizontal direction parallel to the upper surface of the first semiconductor chip 100 or the lower surface of the second semiconductor chip 200. The upper surface of the first semiconductor chip 100 may refer to a surface corresponding to a front surface 120_1 of a first semiconductor device 120 illustrated in FIG. 3. The lower surface of the second semiconductor chip 200 may refer to a surface corresponding to a front surface 220_1 of a second semiconductor device 220 illustrated in FIG. 3. The horizontal direction may include a first direction (e.g., direction D1) and/or a second direction (e.g., direction D2) that are parallel to the surfaces.

The first semiconductor chip 100 may include a first semiconductor substrate 110 and a first semiconductor device 120 disposed on the first semiconductor substrate 110 in the chip region CR. At least one first bottom bonding pad BBP_1 disposed on the first region R_1 and electrically connected to the first semiconductor device 120 may be placed on the first semiconductor device 120. At least one second bottom bonding pad BBP_2 disposed on the second region R_2 and electrically insulated from the first semiconductor device 120 may be placed on the first semiconductor device 120. At least one third bottom bonding pad BBP_3 disposed on the third region R_3 and electrically insulated from the first semiconductor device 120 may be disposed on the first semiconductor device 120. A first insulating layer 142 included in the bonding region BR may be placed on the first semiconductor device 120. Specifically, the first insulating layer 142 may be disposed on the front surface 120_1 of the first semiconductor device 120. At least one first bottom bonding pad BBP_1, at least one second bottom bonding pad BBP_2, and at least one third bottom bonding pad BBP_3 may be placed in the first insulating layer 142.

The first semiconductor substrate 110 may be a semiconductor substrate including a semiconductor material. For example, the first semiconductor substrate 110 may be a semiconductor substrate made of a semiconductor material, or may be a semiconductor substrate having a semiconductor layer formed on a substrate. For example, the first semiconductor substrate 110 may be made of single crystal or polycrystalline silicon, germanium, silicon-germanium, silicon-on-insulator, or germanium-on-insulator, etc. However, the first semiconductor substrate 110 is not limited thereto, but may include other materials.

The first semiconductor device 120 may include a first semiconductor device layer 122, a first wiring structure 124, and a first intermediate insulating layer 126. The first semiconductor device 120 may include various elements, circuits, etc. that may be suitable as the first semiconductor chip 100. For example, the first semiconductor device layer 122 may include transistors, capacitors, RLC circuits or volatile/non-volatile memory cell structures, etc. The first wiring structure 124 may electrically connect the first semiconductor device layer 122 and the first bottom bonding pad BBP_1. The first wiring structure 124 may include one wiring layer or a plurality of wiring layers stacked with the first intermediate insulating layer 126 interposed therebetween and connected along a predetermined path through a contact plug, etc.

The wiring layer and/or the contact plug of the first wiring structure 124 may include various conductive materials with a single layer or a plurality of layers. For example, the wiring layer and/or the contact plug of the first wiring structure 124 may include at least one of copper, aluminum, tungsten, nickel, gold, tin, manganese, cobalt, and titanium, or an alloy including the same. However, the material of the first wiring structure 124 is not limited to the above-described embodiments.

The first intermediate insulating layer 126 and/or the first insulating layer 142 may include various insulating materials with a single layer or a plurality of layers. For example, the first intermediate insulating layer 126 and/or the first insulating layer 142 may include at least one of silicon oxide, silicon nitride, and silicon carbon nitride (SiCN).

The second semiconductor chip 200 may include a second semiconductor substrate 210 and a second semiconductor device 220 disposed in the chip region CR on the second semiconductor substrate 210. At least one first top bonding pad TBP_1 disposed on the first region R_1 and electrically connected to the second semiconductor device 220 may be placed on the second semiconductor device 220. At least one second top bonding pad TBP_2 disposed on the second region R_2 and electrically insulated from the second semiconductor device 220 may be placed on the second semiconductor device 220. At least one third top bonding pad TBP_3 disposed in the third region R_3 and electrically insulated from the second semiconductor device 220 may be placed on the second semiconductor device 220. A second insulating layer 144 included in the bonding region BR may be placed on the second semiconductor device 220.

Specifically, the second insulating layer 144 may be disposed on the front surface 220_1 of the second semiconductor device 220. At least one first top bonding pad TBP_1, at least one second top bonding pad TBP_2, and the third top bonding pad TBP_3 may be placed in the second insulating layer 144.

The second semiconductor substrate 210 may be a semiconductor substrate including a semiconductor material. For example, the second semiconductor substrate 210 may be a semiconductor substrate made of a semiconductor material, or may be a semiconductor substrate having a semiconductor layer formed on a substrate. For example, the second semiconductor substrate 210 may be made of single crystal or polycrystalline silicon, germanium, silicon-germanium, silicon-on-insulator, or germanium-on-insulator, etc. However, the second semiconductor substrate 210 is not limited thereto, but may include other materials.

The second semiconductor device 220 may include a second semiconductor device layer 222, a second wiring structure 224, and a second intermediate insulating layer 226. The second semiconductor device 220 may include various elements, circuits, etc. that may be suitable as the second semiconductor chip 200. For example, the second semiconductor device layer 222 may include transistors, capacitors, RLC circuits or volatile/nonvolatile memory cell structures, etc. The second wiring structure 224 may electrically connect the second semiconductor device layer 222 and the first top bonding pad TBP_1. The second wiring structure 224 may include a single wiring layer or a plurality of wiring layers stacked with the second intermediate insulating layer 226 interposed therebetween and connected along a predetermined path through a contact plug, etc. At least one of the structure, the material or the alignment of the second semiconductor device layer 222 and the second wiring structure 224 may be different from those of the first semiconductor device layer 122 and the first wiring structure 124.

The wiring layer and/or the contact plug of the second wiring structure 224 may include various conductive materials with a single layer or a plurality of layers. For example, the wiring layer and/or the contact plug of the second wiring structure 224 may include at least one of copper, aluminum, tungsten, nickel, gold, tin, manganese, cobalt, and titanium, or an alloy including the same. However, the material of the second wiring structure 224 is not limited to the above-described embodiments.

The second intermediate insulating layer 226 and/or the second insulating layer 144 may include various insulating materials with a single layer or a plurality of layers. For example, the second intermediate insulating layer 226 and/or the second insulating layer 144 may include at least one of silicon oxide, silicon nitride, and silicon carbon nitride (SiCN).

The first semiconductor device 120 of the first semiconductor chip 100 and the second semiconductor device 220 of the second semiconductor chip 200 may face each other. When a bonding surface of the first semiconductor chip 100 (i.e., a surface on which the first insulating layer 142, at least one first bottom bonding pad BBP_1, at least one second bottom bonding pad BBP_2, and at least one third bottom bonding pad BBP_3 are placed), and a bonding surface of the second semiconductor chip 200 (i.e., a surface on which the second insulating layer 144, at least one first top bonding pad TBP_1, at least one second top bonding pad TBP_2, and at least one third top bonding pad TBP_3 are placed) face each other, and the first semiconductor chip 100 and the second semiconductor chip 200 may be bonded using a hybrid bonding process to form the semiconductor device 10.

The semiconductor device 10 may include the first semiconductor device 120 disposed on the first semiconductor substrate 110 and the second semiconductor device 220 disposed on the second semiconductor substrate 210. The first semiconductor device 120 and the second semiconductor device 220 may face each other. When a bonding surface of the first semiconductor device 120 (i.e., a surface on which the first insulating layer 142, at least one first bottom bonding pad BBP_1, at least one second bottom bonding pad BBP_2, and at least one third bottom bonding pad BBP_3 are placed), and a bonding surface of the second semiconductor device 220 (i.e., a surface on which the second insulating layer 144, at least one first top bonding pad TBP_1, at least one second top bonding pad TBP_2, and at least one third top bonding pad TBP_3 are placed) face each other, the semiconductor device 10 may be formed by bonding the two bonding surfaces through a hybrid bonding process.

The semiconductor device 10 may include the bonding region BR and a bonding interface 150 formed between the first semiconductor chip 100 and the second semiconductor chip 20. The bonding region BR may be disposed between the first semiconductor device 120 and the second semiconductor device 220. When the first semiconductor chip 100 and the second semiconductor chip 200 are bonded by hybrid bonding, bumps or solder balls, etc. may not be used, thereby preventing or inhibiting the bonding defects and minimizing the thickness of the semiconductor device 10.

Through the hybrid bonding, the first bottom bonding pad BBP_1 disposed on the first semiconductor device 120 and the first top bonding pad TBP_1 disposed on the second semiconductor device 220 may be bonded to form the first bonding pad BP_1. In addition, the second bonding pad BP_2 may be formed by bonding the second bottom bonding pad BBP_2 disposed on the first semiconductor device 120 and the second top bonding pad TBP_2 disposed on the second semiconductor device 220 through the hybrid bonding. In addition, the third bonding pad BP_3 may be formed by bonding the third bottom bonding pad BBP_3 disposed on the first semiconductor device 120 and the third top bonding pad TBP_3 disposed on the second semiconductor device 220 through the hybrid bonding. The third bonding pad BP_3 may surround or extend around at least one first bonding pad BP_1. The third bonding pad BP_3 may surround or extend around the first region R_1 by extending in a line (or linear) shape along the third region R_3 to form a closed curve in the horizontal direction. In addition, the first insulating layer 142 and the second insulating layer 144 may be bonded.

The first bonding pad BP_1 may be electrically connected to at least one of the first semiconductor device 120 and the second semiconductor device 220. The first bonding pad BP_1 may be disposed on the first region R_1 of the bonding region BR. The second bonding pad BP_2 may be electrically insulated from the first semiconductor device 120 and the second semiconductor device 220. The second bonding pad BP_2 may be disposed on the second region R_2 of the bonding region BR. The third bonding pad BP_3 may be electrically insulated from the first semiconductor device 120 and the second semiconductor device 220. The third bonding pad BP_3 may be disposed on the third region R_3 of the bonding region BR.

The first bonding pad BP_1, the second bonding pad BP_2, and the third bonding pad BP_3 may include the same metal. For example, the first bonding pad BP_1, the second bonding pad BP_2, and the third bonding pad BP_3 may be bonded in a copper-to-copper hybrid bonding structure including copper. The first bonding pad BP_1, the second bonding pad BP_2, and the third bonding pad BP_3 may be bonded by mutual diffusion of metals (e.g., copper) constituting bonding pads during an annealing process. For example, the first bonding pad BP_1 may be bonded by mutual diffusion of metals constituting the first bottom bonding pad BBP_1 and the first top bonding pad TBP_1 during an annealing process. The first bonding pad BP_1, the second bonding pad BP_2, and the third bonding pad BP_3 may include at least one of aluminum, tungsten, nickel, gold, tin, manganese, cobalt, titanium, and tantalum, or an alloy thereof, or further include copper with the above-described metal or an alloy thereof, or a composite layer of metal oxide and metal layer. According to another example, the first bonding pad BP_1, the second bonding pad BP_2, and the third bonding pad BP_3 may include different materials.

The first insulating layer 142 and the second insulating layer 144 may be coupled through direct contact. The first insulating layer 142 and the second insulating layer 144 may be bonded through direct contact to form a dielectric-dielectric bonding structure. The first insulating layer 142 and the second insulating layer 144 may have the same insulating material. The first insulating layer 142 and the second insulating layer 144 may include silicon carbide (SiCN) in at least a contacting portion. The first insulating layer 142 and the second insulating layer 144 may have a relatively stronger bonding intensity by coupling (e.g., covalent coupling) of material or elements included in the first insulating layer 142 and the second insulating layer 144 during an annealing process.

Referring to FIG. 4, a semiconductor device 11 according to some embodiments of the present disclosure may be formed by hybrid bonding between a first semiconductor chip 100 including a chip region CR and a second semiconductor chip 200 including a chip region CR. The semiconductor device 10 may include a bonding region BR formed between respective chip regions CR of the first semiconductor chip 100 and the second semiconductor chip 200. The bonding region BR may include a first region R_1, a second region R_2, and a third region R_3 disposed between the first region R_1 and the second region R_2. For ease of explanation, the description below will focus on the configurations different from those in FIG. 1 to FIG. 3.

According to some embodiments of the present disclosure, the third bonding pad BP_3 of the semiconductor device 10 may at least partially overlap at least one of the first semiconductor device 120 and the second semiconductor device 220 in the horizontal direction (e.g., the first direction-direction D1). The horizontal direction may refer to, for example, a direction parallel to the front surface 120_1 of the first semiconductor device 120 and the front surface 220_1 of the second semiconductor device 220. The third bottom bonding pad BBP_3 disposed on the first semiconductor device 120 may protrude or extend toward the first semiconductor device 120 in a third direction D3. The third bottom bonding pad BBP_3 disposed on the first semiconductor device 120 may at least partially overlap at least part of the first semiconductor device 120 in the horizontal direction. The third top bonding pad TBP_3 disposed on the second semiconductor chip 200 may protrude or extend toward the second semiconductor device 220 in the third direction (e.g., direction D3). The third top bonding pad TBP_3 disposed on the second semiconductor chip 200 may overlap at least part of the second semiconductor device 220 in the horizontal direction.

Referring to FIG. 5, the semiconductor device 10 according to some embodiments of the present disclosure may be formed by bonding the first semiconductor chip 100 including the chip region CR and the second semiconductor chip 200 including the chip region CR by hybrid bonding. The semiconductor chip 100 may include the bonding region BR formed between the chip regions CR between the first semiconductor chip 100 and the second semiconductor chip 200. The bonding region BR may include the first region R_1, the second region R_2, and the third region R_3 disposed between the first region R_1 and the second region R_2. For ease of explanation, the description below will focus on the configurations different from those in FIG. 1 to FIG. 4.

According to some embodiments of the present disclosure, the first bonding pad BP_1 may include a misaligned bonding pad with a non-overlapping area, which is not aligned in the vertical direction (e.g., the third direction-direction D3). The vertical direction may be referred to as, for example, a direction perpendicular to the front surface of the first semiconductor device 120 of the first semiconductor chip 100. The first bottom bonding pad BBP_1 disposed on the first semiconductor device 120 and the first top bonding pad TBP_1 disposed on the second semiconductor device 220 may not overlap in the vertical direction (e.g., the first bottom bonding pad BBP_1 overlaps only a portion of the first top bonding pad TBP_1 in the vertical direction). The first bonding pad BP_1 may be insulated from the first semiconductor device 120 and the second semiconductor device 220. The third bonding pad BP_3 may prevent or inhibit the propagation of cracks that may occur due to the misaligned first bonding pad BP_1 from the inside of the third region R_1.

Referring to FIG. 6A and FIG. 6B, the semiconductor device 10 according to some embodiments of the present disclosure may be formed by bonding the first semiconductor chip 100 including the chip region CR and the second semiconductor chip 200 including the chip region CR through hybrid bonding. The semiconductor device 10 may include the bonding region BR formed between the respective chip regions CR of the first semiconductor chip 100 and the second semiconductor chip 200. The bonding region BR may include the first region R_1, the second region R_2, and the third region R_3 disposed between the first region R_1 and the second region R_2. For ease of explanation, the description below will focus on the configurations different from those in FIG. 1 to FIG. 5.

According to some embodiments of the present disclosure, void V may be formed when the third bottom bonding pad BBP_3 is bonded to the third top bonding pad TBP_2 through hybrid bonding. The void V may occur when particles or other residues remain on the bonding interface. However, as described above, the third bonding pad BP_2 may extend along the third region R_3 in a line (or linear) shape to form a closed curve in the horizontal direction. Therefore, the void V may be removed or blocked by mutual diffusion of metals constituting the third bottom bonding pad BBP_3 and the third upper bonding pad TBP_3 during an annealing process. Accordingly, the third bonding pad BP_3 may effectively seal and protect the inside of the first region R_1 in the bonding region BR.

Referring to FIG. 7, the semiconductor device 11 according to some embodiments of the present disclosure may be formed by bonding the first semiconductor chip 100 including the chip region CR to the second semiconductor chip 200 including the chip region CR through hybrid bonding. The semiconductor device 10 may include the bonding region BR formed between the respective chip regions CR of the first semiconductor chip 100 and the second semiconductor chip 200. The bonding region BR may include the first region R_1, the second region R_2, and the third region R_3 disposed between the first region R_1 and the second region R_2. For ease of explanation, the description below will focus on the configurations different from those in FIG. 1 to FIG. 6B.

According to some embodiments of the present disclosure, at least part of the third bonding pad BP_3 of the semiconductor device 10 may overlap at least one of the first semiconductor device 120 or the second semiconductor device 220 (e.g., the second direction-direction D2). Accordingly, cracks that may occur in the second region R_2 while the first semiconductor chip 100 and the second semiconductor chip 200 are bonded may be effectively prevented or inhibited from propagation.

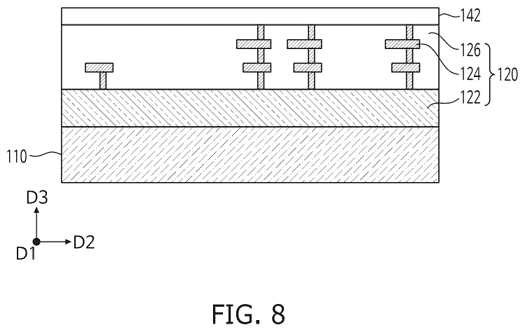

FIG. 8 to FIG. 11 are views to explain a manufacturing method of the third bonding pad BP_3 according to some embodiments of the present disclosure. For ease of explanation, the description below will focus on the configurations different from those in FIG. 1 to FIG. 7. The drawings in FIG. 8 to FIG. 11 are in the same direction as the cross-sectional view taken along line B-B′ of FIG. 1.

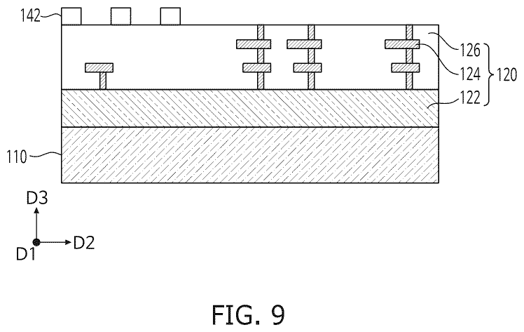

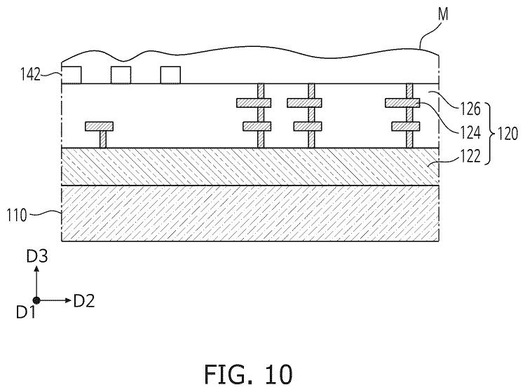

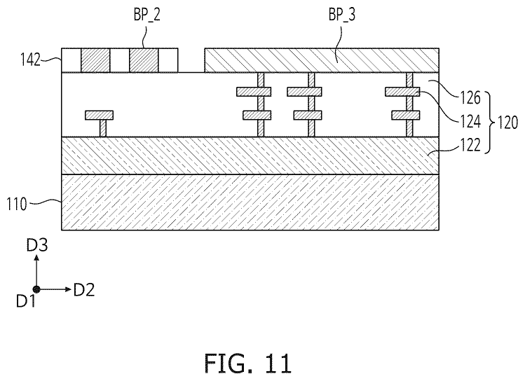

Referring to FIG. 8, after the first semiconductor device 120 is formed on the first semiconductor substrate 110, the first insulating layer 142 may be formed. Referring to FIG. 9, an etching process for patterning the first insulating layer 142 may be performed. Referring to FIG. 10, a metal layer M may be deposited on the patterned first insulating layer 142. The metal layer M may be used for generating the first bonding pad BP_1, the second bonding pad BP_2, and the third bonding pad BP_3 described above with reference to FIG. 1 to FIG. 7. Referring to FIG. 11, the first bonding pad BP_1, the second bonding pad BP_2, and the third bonding pad BP_3 may be manufactured by removing at least part of the metal layer M through a CMP or an etching process, etc.

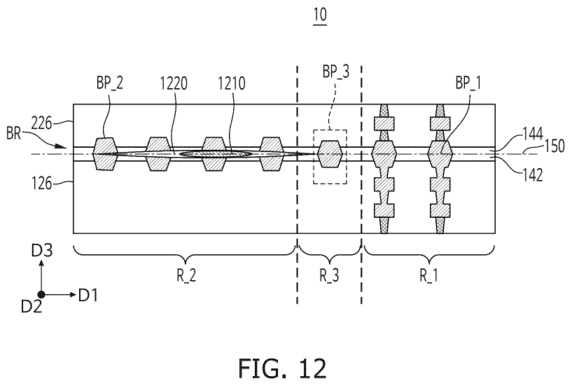

FIG. 12 is a view illustrating a part of the semiconductor device 10 on which the third bonding pad BP_3 is formed. For ease of explanation, the description below will focus on the configurations different from those in FIG. 1 to FIG. 11.

Referring to FIG. 12, the third region R_3 including the third bonding pad BP_3 may be placed between the first region R_1 including the first bonding pad BP_1 and the second region R_2 including the second bonding pad BP_2. The first bonding pad BP_1 may be electrically connected to an integrated circuit component of the semiconductor device 10, and the first region R_1 may correspond to a main operation region of the semiconductor device 10. The second bonding pad BP_2 may be electrically insulated from the integrated circuit component of the semiconductor device 10, and the second region R_2 may correspond to a dummy region of the semiconductor device 10.

The third bonding pad BP_3 disposed on the third region R_3 may prevent or inhibit particles 1210 or voids 1220 generated during the bonding of the second bonding pad BP_2 of the second region R_2, or cracks by the particles or voids from propagation to the first bonding pad BP_1 of the first region R_1. Accordingly, the reliability of semiconductor device may be enhanced by preventing or inhibiting quality deterioration or defect occurrence of the semiconductor device 10.

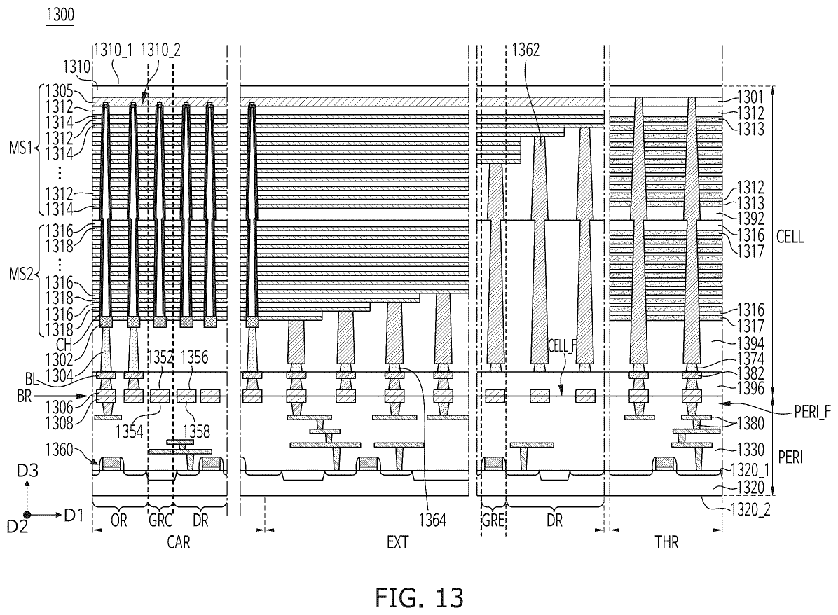

FIG. 13 is a view illustrated to explain a semiconductor device 1300 according to some embodiments of the present disclosure.

Referring to FIG. 13, a semiconductor device 1300 according to some embodiments of the present disclosure may include a cell structure CELL and a peripheral circuit structure PERI. The cell structure CELL may correspond to the first semiconductor chip 100 illustrated in FIG. 1 to FIG. 12, and the peripheral circuit structure PERI may correspond to the second semiconductor chip 200 illustrated in FIG. 1 to FIG. 12. The semiconductor device 1300 may correspond to the semiconductor device 10 illustrated in FIG. 1 to FIG. 12.

The cell structure CELL may include a cell substrate 1310, a first mold structure MS1, a second mold structure MS2, a channel structure CH, a channel pad 1302, a bit line BL, a word line contact 1362, etc. The cell substrate 1310 may correspond to the first semiconductor substrate 110 or the second semiconductor substrate 210 illustrated in FIG. 1 to FIG. 12. The cell substrate 1310, the first mold structure MS1, the second mold structure MS2, the channel structure CH, the channel pad 1302, the bit line BL, the word line contact 1362, etc., may correspond to the first semiconductor device 120 or the second semiconductor device 220 illustrated in FIG. 1 to FIG. 12. The first mold structure MS1, the second mold structure MS2 and the channel structure CH may correspond to the first semiconductor device layer 122 or the second semiconductor device layer 222. The channel pad 1302, the bit line BL and the word line contact 1362 may correspond to the first wiring structure 124 or the second wiring structure 224.

The cell substrate 1310 may include a cell array region CAR, an extension region EXT, and a through region THR. The cell region CAR may include an operation region OR, a cell array guard region GRC, and a dummy region DR. The operation region OR may correspond to the first region R_1 of the semiconductor device 10 illustrated in FIG. 1 to FIG. 12. The cell array guard region GRC may correspond to the third region R_3 of the semiconductor device 10 illustrated in FIG. 1 to FIG. 12. The dummy region DR may correspond to the second region R_2 of the semiconductor device 10 illustrated in FIG. 1 to FIG. 12.

A memory cell array including a plurality of memory cells may be formed on the cell array region CAR. The channel structure CH, the first mold structure MS1, the second mold structure MS2, the bit line BL, etc. may be arranged on the cell array region CAR.

The extension region EXT may be placed at the periphery of the cell array region CAR. For example, the extension region EXT may surround or extend around the cell array region CAR. The word line contact 1362, the support structure, etc. may be placed on the extension region EXT.

The through region THR may be disposed outside the extension region EXT. For example, the through region THR may be disposed on one end of the extension region EXT, but the present disclosure is not limited thereto. A through via may be placed on the through region THR.

The cell substrate 1310 may include a semiconductor substrate such as a silicon substrate, a germanium substrate, or a silicon-germanium substrate. In some embodiments, the cell substrate 1310 may include a silicon-on-insulator (SOI) substrate, a germanium-on-insulator (GOI) substrate, etc. According to some embodiments of the present disclosure, the cell substrate 1310 may include polysilicon (poly Si).

The cell substrate 1310 may include a first side 1310_1 and a second side 1310_2 facing the first side 1310_1. The first mold structure MS1 and the channel structure CH may be formed on the second side 1310_2 of the cell substrate 1310. The second side 1310_2 of the cell substrate 1310 may be referred to as a front side (or upper surface) of the cell substrate 1310. The first side 1310_1 of the cell substrate 1310 may be referred to as a back side (or lower surface) of the cell substrate 1310.

The first mold structure MS1 may be formed on the second side 1310_2 of the cell substrate 1310. The first mold structure MS1 may include a plurality of first mold insulating layers 1312 and a plurality of first gate electrodes 1314 alternately stacked in the third direction D3. Each of the plurality of first mold insulating layers 1312 and each of the plurality of first gate electrodes 1314 may have a layered structure extending parallel to the second side 1310_2 of the cell substrate 1310. The first gate electrode 1314 may be spaced apart from the first mold insulating layer 1312 and sequentially stacked on the cell substrate 1310.

The second mold structure MS2 may be formed on the first mold structure MS1. The second mold structure MS2 may include a plurality of second mold insulating layers 1316 and a plurality of second gate electrodes 1318 alternately stacked. Each of the plurality of second mold insulating layers 1316 and each of the plurality of second gate electrodes 1318 may have a layered structure extending parallel to the second side 1310_2 of the cell substrate 1310. The second gate electrode 1318 may be spaced apart from the second mold insulating layer 1316 and sequentially stacked on the first mold structure MS1.

According to some embodiments of the present disclosure, part of the plurality of first gate electrodes 1314 may be used as a ground select line (GSL) and an erasing control line (ECL) of the semiconductor memory device. The erasing control line may be used as a gate electrode of an erasing transistor. The erasing transistor may cause gate-induced drain leakage (GIDL) to perform erasing operations of a plurality of memory cell transistors. The first gate electrode 1314 adjacent to the erasing control line may be used as the ground select line. However, the present disclosure is not limited thereto. The arrangement and the number of the erasing control lines and the ground select lines may vary.

According to some embodiments of the present disclosure, part of the plurality of second gate electrodes 1318 may be used as a string select line (SSL) of the semiconductor memory device. For example, the second gate line 1318 adjacent to the bit line BL among the plurality of second gate electrodes 1318 may be used as the string select line. However, the present disclosure is not limited thereto. The arrangement and the number of the string select lines may vary.

Each of the first mold insulating layer 1312 and the second mold insulating layer 1316 may include an insulating material. Each of the first mold insulating layer 1312 and the second mold insulating layer 1316 may include, for example, at least one of silicon oxide, silicon nitride, and silicon oxynitride, but the present disclosure is not limited thereto.

Each of the first gate electrode 1314 and the second gate electrode 1318 may include a conductive material. Each of the first gate electrode 1314 and the second gate electrode 1318 may include, for example, metals such as titanium-gold alloy (Au-Ti), tungsten (W), aluminum (Al), cobalt (Co), nickel (Ni), copper (Cu), silver (Ag), palladium (Pd), and semiconductor materials such as gold or silicon, but the present disclosure is not limited thereto.

Referring to FIG. 13, the number of mold structures MS1 and MS2 is illustrated as being two (2), but the present disclosure is not limited thereto. For example, the number of mold structures MS1 and MS2 may be three (3), four (4), or more.

The channel structure CH may penetrate or extend into each of the first mold structure MS1 and the second structure MS2. For example, the channel structure CH may penetrate (or extend into) and intersect each of the plurality of first mold insulating layers 1312 and each of the plurality of first gate electrodes 1314. The channel structure CH may penetrate (or extend into) and intersect each of the plurality of second mold insulating layers 1316 and each of the plurality of second gate electrodes 1318. The channel structure CH may extend in the third direction D3. The channel structure CH may have a pillar shape (e.g., a cylindrical shape) extending in the third direction D3.

The channel structure CH may include a bending (or nonlinear) portion between the first mold structure MS1 and the second structure MS2. According to some embodiments of the present disclosure, the cross-section of the channel structure CH placed in the first mold structure MS1 may have an inclined surface with a width that narrows toward the cell substrate 1310.

However, the present disclosure is not limited thereto.

According to some embodiments of the present disclosure, the channel structure CH may be arranged in a zigzag shape. For example, the channel structure CH may alternate in the first direction D1 and the second direction D2. The channel structure CH in the zigzag shape may improve the integration density of the semiconductor device. According to some embodiments of the present disclosure, the channel structures CH may be arranged in a honeycomb shape.

The channel structure CH may include an ion storage layer, an ion conductive layer, a channel layer, and a filling insulating layer sequentially placed on the plurality of first gate electrodes 1314. For example, a channel hole extending in the third direction D3 and penetrating or extending into the mold structures MS1 and MS2 may be formed. The ion storage layer, the ion conductive layer, the channel layer, and the filling insulating layer may be sequentially stacked in the channel hole.

The semiconductor memory device may operate at a low voltage (e.g., 10 V or less) by the components of the channel structure CH, thereby reducing a gate length Lg or an inter-gate space Ls. Accordingly, the integration density and electrical characteristics of the semiconductor device may be improved.

The channel pad 1302 may be arranged on the channel structure CH. The channel pad 1302 may be placed on the upper portion of the channel structure CH and electrically connected to the channel structure CH. The channel pad 1302 may include, for example, polysilicon doped with impurities, but the present disclosure is not limited thereto. The channel pad 1302 may be in contact with and electrically connected to the bit line contact 1364.

The bit line BL may be formed on the mold structures MS1 and MS2. The bit line BL may contact a plurality of channel structure CH extending and placed along the second direction D2. For example, the bit line contact 1364 contacting the upper portion of each channel structure CH in a second interlayer insulating layer 1394 may be formed. The bit line BL may be electrically connected to the channel structures CH through the bit line contact 1364.

The word line contact 1362 or the word line structure may contact the gate electrodes 1314 and 1318, respectively. For example, the word line contact 1362 may extend in the third direction D3 and contact each of the gate electrodes 1314 and 1318. According to some embodiments of the present disclosure, the word line contact 1362 may include a bending (or nonlinear) portion between the first mold structure MS1 and the second mold structure MS2.

According to some embodiments of the present disclosure, the mold structures MS1 and MS2 of the through region THR may include a plurality of mold sacrificial films 1313 and 1317 and the plurality of mold insulating layers 1312 and 1316 alternately stacked on the cell substrate 1310 and/or the insulating substrate 1301. Each of the plurality of mold sacrificial films 1313 and 1317 and the plurality of mold insulating layers 1312 and 1316 may be a layered structure extending parallel to the upper side of the cell substrate 1310. The plurality of mold sacrificial films 1313 and 1317 may be spaced apart from the plurality of mold insulating layers 1312 and 1316 to be sequentially stacked on the cell substrate 1310.

According to some embodiments of the present disclosure, the first mold structure MS1 of the through region THR may include a plurality of first mold sacrificial films 1313 and a plurality of first mold insulating layers 1312 alternately stacked on the cell substrate 1310. The second mold structure MS2 on the through region THR may include a plurality of second mold sacrificial films 1317 and a plurality of second mold insulating layers 1316 alternately stacked on the first mold structure MS1.

The mold sacrificial films 1313 and 1317 each may include an insulating material, for example, at least one of silicon oxide, silicon nitride, and silicon oxynitride, but the present disclosure is not limited thereto. According to some embodiments of the present disclosure, the mold sacrificial films 1313 and 1317 may include a material having an etch selectivity with respect to the mold insulating layers 1312 and 1316. For example, the mold insulating layers 1312 and 1316 may include silicon oxide, and the mold sacrificial films 1313 and 1317 may include silicon nitride.

The interlayer insulating films 1392 and 1394 may be formed on the cell substrate 1310 to cover or at least partially overlap the mold structures MS1 and MS2. According to some embodiments of the present disclosure, the interlayer insulating films 1392 and 1394 may include a first interlayer insulating film 1392 and a second interlayer insulating film 1394 sequentially stacked on the cell substrate 1310. The first interlayer insulating film 1392 may cover or at least partially overlap the first mold structure MS1, and the second interlayer insulating film 1394 may cover or at least partially overlap the second mold structure MS2. The first and second interlayer insulating films 1392 and 1394 may include at least one of, for example, silicon oxide, silicon oxynitride, and a low-k material having a lower permittivity than silicon oxide, but the present disclosure is not limited thereto.

A through via may be placed on the through region THR. For example, the through via may extend in the third direction D3 and into the mold structures MS1 and MS2 on the through region THR. According to some embodiments of the present disclosure, the through via may include a bending (or nonlinear) portion between the first mold structure MS1 and the second mold structure MS2. The through via is illustrated as penetrating or extending into the mold structures MS1 and MS2 only, but it is only example. According to another example, the through via may be placed outside the mold structures MS1 and MS2 and may not extend into or penetrate the mold structures MS1 and MS2.

The word line contact 1362 and through via each may contact a first wiring structure 1382 on the first and second interlayer insulating films 1392 and 1394. For example, a wiring insulating film 1396 may be formed on the second interlayer insulating film 1394. The first wiring structure 1382 may be formed in the wiring insulating film 1396. The word line contact 1362 and the through via 182 each may be connected to the first wiring structure 1382 by a contact via 1374. Although not specifically shown, the first wiring structure 1382 may be connected to the bit line BL.

Although not shown, a support structure may be formed in the mold structures MS1 and MS2 and on the extension region EXT. The support structure may be formed in the similar shape as the channel structure CH to reduce the stress applied to the mold structures MS1 and MS2.

The peripheral circuit region PERI may include a peripheral circuit substrate 1320, a peripheral circuit element 1360, and a peripheral circuit wiring structure 1380. The peripheral circuit substrate 1320 may correspond to the first semiconductor substrate 110 or the second semiconductor substrate 210 illustrated in FIG. 1 to FIG. 12. The peripheral circuit element 1360 and the peripheral circuit wiring structure 1380 may correspond to the first semiconductor device 120 or the second semiconductor device 220 illustrated in FIG. 1 to FIG. 12. Specifically, the peripheral circuit element 1360 may correspond to the first semiconductor device layer 122 or the second semiconductor device layer 222 illustrated in FIG. 1 to FIG. 12, and the peripheral circuit wiring structure 1380 may correspond to the first wiring structure 124 or the second wiring structure 224 illustrated in FIG. 1 to FIG. 12.

The peripheral circuit substrate 1320 may be placed under the cell substrate 1310. For example, the upper surface of the peripheral circuit substrate 1320 may face the second surface 1310_2 of the cell substrate 1310. The peripheral circuit substrate 1320 may include, for example, a semiconductor substrate such as a silicon substrate, a germanium substrate, or a silicon-germanium substrate. In some embodiments, the peripheral circuit substrate 1320 may include a silicon-on-insulator (SOI) substrate, a germanium-on-insulator (GOI) substrate, or etc.

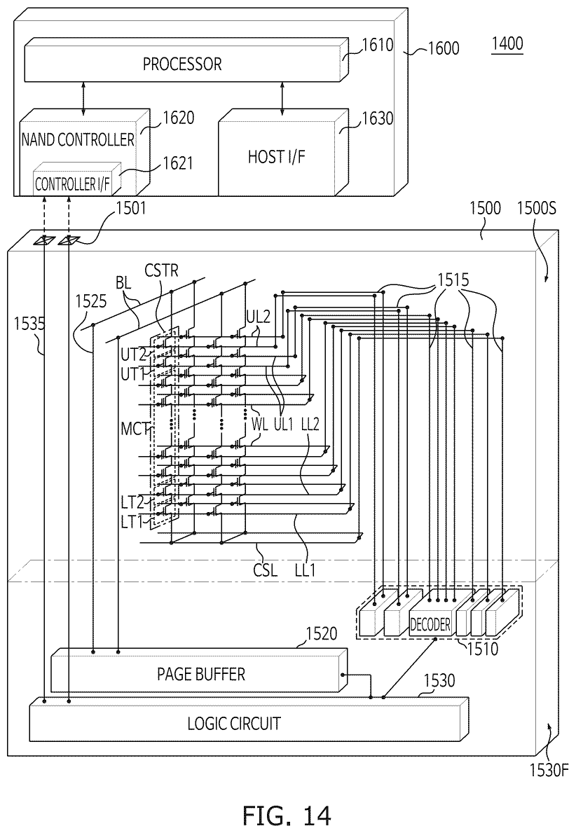

The peripheral circuit element 1360 may be formed on the peripheral circuit substrate 1320. The peripheral circuit element 1360 may form a peripheral circuit that controls the operation of the semiconductor memory device. For example, the peripheral circuit element 1360 may include a logic circuit 1530, a page buffer 1520, a decoder circuit 1510, etc., as shown in FIG. 14. The surface of the peripheral circuit substrate 1320 including the peripheral circuit element 1360 arranged thereon may be referred to as a front side of the peripheral circuit substrate 1320. The surface of the peripheral circuit substrate 1320 opposite to the front side of the peripheral circuit substrate 1320 may be referred to as a back side of the peripheral circuit substrate 1320.

The peripheral circuit element 1360 may include, for example, a transistor, but may not be limited thereto. For example, the peripheral circuit element 1360 may include various passive elements such as capacitors, resistors, inductors, etc. in addition to various active elements such as transistors, etc.

The peripheral circuit wiring structure 1380 may be formed on the peripheral circuit element 1360. For example, a wiring insulating film 1330 may be formed on the front side of the peripheral circuit substrate 1320, and the peripheral circuit wiring structure 1380 may be formed in the wiring insulating film 1330. The peripheral circuit wiring structure 180 may be electrically connected to the peripheral circuit element 1360. The number or the arrangement of layers of the peripheral circuit wiring structure 1380 are only examples and are not limited thereto.

A semiconductor device 1300 may include a common source plate 1305. The common source plate 1305 may be placed on the second surface 1310_2 of the cell substrate 1310. The common source plate 1305 may contact the channel structure CH. For example, the common source plate 1305 may be electrically connected to a channel layer of the channel structure CH. The common source plate 1305 may be used as a common source line of the semiconductor device. The first mold structure MS1 and the second mold structure MS2 may be placed on the common source plate 1305 (e.g., under the common source plate). The common source plate 1305 may include, for example, polycrystalline silicon or metal doped with impurities, but the present disclosure is not limited thereto.

The semiconductor device 1300 may have a chip-to-chip (C2C) structure. The C2C structure may be formed by manufacturing an upper chip including the memory cell region CELL on a first wafer (e.g., the cell substrate 1310), a lower chip including the peripheral circuit region PERI on a second wafer (e.g., the peripheral circuit substrate 1320) different from the first wafter, and bonding the upper chip to the lower chip by using a bonding technique. The bonding region BR formed through the above process may correspond to the bonding region BR illustrated in FIG. 1 to FIG. 12.

According to some embodiments of the present disclosure, the bonding region BR formed on the cell array region CAR may include an operation region OR, a cell array guard region GRC, and a dummy region DR. As described above, the operation region OR, the cell array guard region GRC, and the dummy region DR may correspond to the first region R_1, the third region R_3, and the second region R_2 illustrated in FIG. 1 to FIG. 12, respectively.

A first bonding pad may be formed on the operation region OR by bonding a first top bonding pad 1306 to a first bottom bonding pad 1308. The first bonding pad may correspond to the first bonding pad BP_1 illustrated in FIG. 1 to FIG. 12. A second bonding pad may be formed on the dummy region DR by bonding a second top bonding pad 1356 to a second bottom bonding pad 1358. The second bonding pad may correspond to the second bonding pad BP_2 illustrated in FIG. 1 to FIG. 12. A third bonding pad may be formed on the cell array guard region GRC by bonding a third top bonding pad 1352 to a third bottom bonding pad 1354. The third bonding pad may correspond to the third bonding pad BP_3 illustrated in FIG. 1 to FIG. 12.

For example, the bonding region BR formed on the expansion region EXT may include an expansion guard region GRE and a dummy region DR. The expansion guard region GRE and the dummy region DR each may correspond to the third region R_3 and the second region R_2 illustrated in FIG. 1 to FIG. 12. The third bonding pad may be formed on the guard region GRE by bonding the third top bonding pad to the third lower bonding pad. The third bonding pad may correspond to the third bonding pad BP_3 illustrated in FIG. 1 to FIG. 12. The second bonding pad may be formed on the dummy region DR by bonding the second top bonding pad to the second lower bonding pad. The second bonding pad may correspond to the second bonding pad BP_2 illustrated in FIG. 1 to FIG. 12.

FIG. 14 is an example block view illustrated to explain an electronic system 1400 According to some embodiments of the present disclosure.

Referring to FIG. 14, an electronic system 1400 according to some embodiments of the present disclosure may include a semiconductor device 1500 and a controller 1600 electrically connected to the semiconductor device 1500, which may correspond to the semiconductor devices described in FIG. 1 to FIG. 13. The electronic system 1400 may be a storage device including one or a plurality of semiconductor devices 1500 or an electronic device including the storage device. For example, the electronic system 1400 may be a solid state drive device (SSD), a Universal Serial Bus (USB), a computing system, a medical device, or a communication device including one or the plurality of semiconductor devices 1500.

The semiconductor device 1500 may be, for example, a NAND flash memory device described above with reference to FIGS. 1 to 13. The semiconductor memory device 1500 may include a first structure 1500F and a second structure 1500S on the first structure 1500F. The first structure 1500F may be a peripheral circuit structure including a decoder circuit 1510, a page buffer 1520, and a logic circuit 1530. The second structure 1500S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1500S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on the embodiments.

According to example embodiments, the upper transistors UT1 and UT2 may include string select transistors, and the lower transistors LT1 and LT2 may include ground select transistors. Gate lower lines LL1 and LL2 may be gate electrodes of the lower transistors LT1 and LT2, respectively. Word lines WL may be gate electrodes of the memory cell transistors MCT, and Gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1510 through first connection wires 1515 extending from within the first structure 1500F to the second structure 1500S. The bit lines BL may be electrically connected to the page buffer 1520 through second connection wires 1525 extending from within the first structure 1500F to the second structure 1500S.

In the first structure 1500F, the decoder circuit 1510 and the page buffer 1520 may execute a control operation for at least one select memory cell transistor among a plurality of memory cell transistors MCT. The decoder circuit 1510 and the page buffer 1520 may be controlled by a logic circuit 1530. The semiconductor memory device 1500 may communicate with a controller 1600 through an input and output pad 1501 electrically connected to the logic circuit 1530. The input and output pad 1501 may be electrically connected to the logic circuit 1530 through an input and output connection wiring line 1535 extending from within the first structure 1500F to the second structure 1500S.

The controller 1600 may include a processor 1610, a NAND controller 1620, and a host interface 1630. According to some embodiments of the present disclosure, the electronic system 1400 may include a plurality of semiconductor devices 1500, and the controller 1600 may control the plurality of semiconductor devices 1500.

The processor 1610 may control the overall operation of the electronic system 1400 including the controller 1600. The processor 1610 may operate according to a predetermined firmware, and control the NAND controller 1620 to access the semiconductor device 1500. The NAND controller 1620 may include a NAND interface (or a controller interface) 1621 that processes communication with the semiconductor device 1500. A control command for controlling the semiconductor device 1500, data for recording in the memory cell transistors MCT of the semiconductor device 1500, data to be read from the memory cell transistors MCT of the semiconductor device 1500, etc. may be transmitted through a NAND interface 1621. A host interface 1630 may provide a communication function between the electronic system 1400 and an external host. When receiving a control command from an external host through the host interface 1630, the processor 1610 may control the semiconductor device 1500 in response to the control command.

Although embodiments of the present disclosure has been described with reference to the drawings, those skilled in the art will understand that the present disclosure is implemented in other various forms without departing from the technical spirits or essential features thereof. Accordingly, it should be understood that the embodiments described above are example in all respects but not restrictive.

While the present disclosure has been described with reference to example embodiments thereof, it is to be understood that the present disclosure is not limited to the example embodiments. It will be apparent to those skilled in the art that various modifications and changes may be made within the scope of the appended claims and their equivalents.

What is claimed is:

1. A semiconductor device, comprising:
a first semiconductor substrate comprising a first semiconductor device;
a second semiconductor substrate comprising a second semiconductor device; and
a bonding region that is between the first semiconductor device and the second semiconductor device and comprises a first region, a second region, and a third region that is between the first region and the second region and extends around the first region, wherein the bonding region comprises:
a first bonding pad on the first region;
a second bonding pad on the second region; and
a third bonding pad on the third region, and
wherein the third bonding pad extends around the first bonding pad.

2. The semiconductor device of claim 1, wherein the third region entirely extends around the first region in a first direction and a second direction that are parallel to an upper surface of the first semiconductor device.

3. The semiconductor device of claim 2, wherein the third bonding pad entirely extends around the first region in the first direction and the second direction and extends in a linear shape along the third region.

4. The semiconductor device of claim 1, wherein:
the first bonding pad comprises a first bottom bonding pad on the first semiconductor device and a first top bonding pad that is on the second semiconductor device and is bonded to the first bottom bonding pad,
the second bonding pad comprises a second bottom bonding pad on the first semiconductor device and a second top bonding pad that is on the second semiconductor device and is bonded to the second bottom bonding pad, and
the third bonding pad comprises a third bottom bonding pad on the first semiconductor device and a third top bonding pad that is on the second semiconductor device and is bonded to the third bottom bonding pad.

5. The semiconductor device of claim 1, wherein the first bonding pad is electrically connected to at least one of the first semiconductor device or the second semiconductor device.

6. The semiconductor device of claim 5, wherein the second bonding pad is electrically insulated from the first semiconductor device and the second semiconductor device.

7. The semiconductor device of claim 6, wherein the third bonding pad is electrically insulated from the first semiconductor device and the second semiconductor device.

8. The semiconductor device of claim 5, wherein:
at least a portion of the third bonding pad overlaps at least one of the first semiconductor device or the second semiconductor device in a first direction, and
the first direction is parallel to an upper surface of the first semiconductor device.

9. The semiconductor device of claim 1, wherein the third bonding pad extends in a linear shape along the third region, and a width of the third bonding pad in a first direction that is parallel to an upper surface of the first semiconductor device is less than or equal to a width of the first bonding pad in the first direction.

10. A semiconductor device, comprising:
a substrate;
a peripheral circuit structure on the substrate;
a cell structure on the peripheral circuit structure; and
a bonding region comprising a first bonding pad, a second bonding pad, and a third bonding pad between the peripheral circuit structure and the cell structure,
wherein the first bonding pad is on a first region of the bonding region,
wherein the second bonding pad is on a second region of the bonding region,
wherein the third bonding pad is on a third region of the bonding region,
wherein the third region is between the first region and the second region and extends around the first region, and
wherein the third bonding pad extends around the first bonding pad.

11. The semiconductor device of claim 10, wherein the cell structure comprises:
a mold structure comprising a plurality of gate electrodes and a mold insulating layer that extends around the plurality of gate electrodes;
a plurality of channel structures that extend into the mold structure in a first direction; and
a plurality of word line structures respectively contacting the plurality of gate electrodes,
wherein the first direction is perpendicular to an upper surface of the substrate.

12. The semiconductor device of claim 10, wherein the third region entirely extends around the first region in a first direction and a second direction that are parallel to an upper surface of the substrate.

13. The semiconductor device of claim 12, wherein the third bonding pad extends in a linear shape along the third region and entirely extends around the first region in the first direction and the second direction.

14. The semiconductor device of claim 10, wherein the first bonding pad is electrically connected to at least one of the cell structure or the peripheral circuit structure.

15. The semiconductor device of claim 14, wherein the second bonding pad and the third bonding pad are electrically insulated from the cell structure and the peripheral circuit structure.

16. The semiconductor device of claim 10, wherein at least a portion of the third bonding pad overlaps at least one of the cell structure or the peripheral circuit structure in a first direction that is parallel to an upper surface of the substrate.

17. The semiconductor device of claim 10, wherein the third bonding pad extends in a linear shape along the third region, and a width of the third bonding pad in a first direction that is parallel to an upper surface of the substrate is less than or equal to a width of the first bonding pad in the first direction.

18. The semiconductor device of claim 10, further comprising a plurality of first bonding pads that comprises the first bonding pad, and wherein, in a first direction that is parallel to an upper surface of the substrate, a distance between the first bonding pad and the third bonding pad is greater than or equal to a distance between a second one of the plurality of first bonding pads and a third one of the plurality of first bonding pads.

19. The semiconductor device of claim 10, wherein the first bonding pad comprises a first bottom bonding pad and a first top bonding pad, and wherein the first bottom bonding pad overlaps a portion of the first top bonding pad in a first direction that is perpendicular to an upper surface of the substrate.

20. A semiconductor device, comprising:
a first semiconductor substrate comprising a first semiconductor device;
a second semiconductor substrate comprising a second semiconductor device; and
a bonding region that is between the first semiconductor device and the second semiconductor device and comprises a first region, a second region, and a third region between the first region and the second region and extending around the first region, and
wherein the bonding region comprises:
a first bonding pad on the first region, wherein the first bonding pad comprises a first bottom bonding pad on the first semiconductor device and a first top bonding pad on the second semiconductor device;
a second bonding pad on the second region, wherein the second bonding pad comprises a second bottom bonding pad on the first semiconductor device and a second top bonding pad on the second semiconductor device; and
a third bonding pad on the third region, wherein the third bonding pad comprises a third bottom bonding pad on the first semiconductor device and a third upper bonding pad on the second semiconductor device,
wherein the third region entirely extends around the first region in a first direction and a second direction that are parallel to an upper surface of the first semiconductor device, and
wherein the third bonding pad extends in a linear shape along the third region and entirely extends around the first region in the first direction and the second direction.
